(19) United States
(12) Patent Application Publication
(10) Pub. No.: US 2015/0285882 A1
(43) Pub. Date: Oct. 8, 2015

(54) PORTABLE SYSTEM AND METHOD FOR MRI IMAGING AND TISSUE ANALYSIS

(71) Applicant: University of Maryland, Baltimore, Baltimore, MD (US)

(72) Inventors: Reuben Mezrich, Baltimore, MD (US); Joshua Mezrich, Madison, WI (US)

(21) Appl. No.: 14/678,173

(22) Filed: Apr. 3, 2015

Related U.S. Application Data
(60) Provisional application No. 61/974,494, filed on Apr. 3, 2014.

(51) Int. Cl. G01R 33/48

(52) U.S. Cl. CPC G01R 33/4828

(57) ABSTRACT

The present invention discloses a portable magnetic resonance method and device for tissue analysis including a magnetic field generator, a radio frequency source, a radio frequency detector, a power source, and a processor configured for receiving radio frequency signals and for analyzing those signals to determine discriminatory tissue characteristics in a planar section of a region of interest within a patient's body, with the magnetic field generator positioned outside of the patient's body, and more preferably hand held in proximity to the patient's body. The processor is configured to direct the radio frequency source to produce a radio frequency field in varying planar sections of the region of interest at Larmor frequencies such that spins resonant with the Larmor frequency in the particular planar section of the region of interest are excited. The processor is further configured to direct the radio frequency detector to receive magnetic resonance signals produced in each planar section of the region of interest in response to the applied radio frequency field, to compute from the acquired magnetic resonance signals a quantitative metric indicative of discriminatory characteristics of differing tissues or other materials within each such planar section, and to produce human discernable output indicative of such quantitative metric.

### CROSS-REFERENCE TO RELATED APPLICATION

This application is based upon and claims the benefit of copending U.S. Provisional Patent Application Ser. No. 61/974,494 entitled “Hand-Held System for MRI Imaging and Tissue Analysis,” filed with the U.S. Patent and Trademark Office on Apr. 3, 2014 by the inventors herein, the specification of which is incorporated herein by reference in its entirety.

### FIELD OF THE INVENTION

The present invention relates generally to magnetic resonance measurements, and more particularly to portable, such as hand-held, magnetic resonance measurement devices for detection of discriminatory tissue characteristics and their methods of use.

### BACKGROUND OF THE INVENTION

There is a rising epidemic of “fatty” liver, which is in part due to the rising epidemic of morbid obesity. Excess fat in the liver (clinically termed hepatic steatosis), if chronic, can be the initiating factor in a cascade of processes that include fibrosis, cirrhosis and ultimately hepatocellular carcinoma (hepatoma). This cascade is exactly that seen in patients with hepatitis, and as treatments are being found for hepatitis induced fatty liver in patients with morbid obesity (so called Non-Alcoholic Steatic Hepatosis or NASH) is becoming the most important risk factor for hepatocellular carcinoma.

Current methods for the assessment of fatty liver carry numerous challenges. The most accurate method for diagnosing fatty liver is biopsy which carries considerable risk—primarily of hemorrhage—even in experienced hands. Chemical Shift MRI imaging provides a sensitive and specific means for quantifying the degree of fat burden in the liver, but it is very expensive. CT is less accurate and has the burden of radiation exposure as well as high cost. Ultrasound is another tool for evaluating and following patients with suspected fatty liver, but it has poor sensitivity (as low as 47% in recent large studies) and is not inexpensive. The value of ultrasound is therefore limited.

Other medical indications have similar diagnostic limitations. Some examples include liver fibrosis, edema in the liver, brain edema, subdural blood in the brain, and blood flow.

Previous efforts have been made to provide portable magnetic resonance systems to diagnose medical indications, including for measuring characteristics of a patient's lung, such as those described in U.S. Patent Application Publication No. US 2014/0155732 A1 of Patz et al., the specification of which is incorporated herein by reference in its entirety.

However, there remains a need for a more reliable and cost effective device that can noninvasively detect tissue properties in a small volume at varied locations in a patient's body, such as (by way of non-limiting example) tissue properties within a patient's liver, and particularly the degree of fat burden within an individual's liver, the presence of bleeding within a patient's body, and other conditions that are detectable by discrimination of tissue properties. It would be desirable to provide a device that can discriminate tissue properties in various parts of a patient's body without requiring complex MRI equipment, and that could provide such functionality within a traditional, non-surgical physician's office setting using ready-to-use, compact, and preferably hand-held equipment.

### SUMMARY OF THE INVENTION

Disclosed herein are portable MRI devices and their methods of use. These devices may also be configured to obtain two-dimensional images.

With regard to certain aspects of an embodiment of the invention, a portable MRI device is provided comprising a magnetic field generator (such as a magnet), a radio frequency source, a radio frequency detector, a power source, and a processor configured for receiving radio frequency signals and for analyzing those signals to determine discriminatory tissue characteristics in a planar section of a region of interest within a patient's body. The magnetic field generator preferably includes a magnetic coil, a permanent magnet, an electromagnet, or a solenoid, and is configured to produce a magnetic field of known field strength within a region of interest in a patient's body, such as a region of interest within a patient's liver that is to be evaluated for fat content, with the magnetic field generator positioned outside of the patient's body, and more preferably hand-held in proximity to the patient's body. The magnetic field generator may also comprise a gradient coil that may be used for localization. The radio frequency source may comprise a coil that may be positioned about the patient's body and configured to apply a radio frequency field to the region of interest, and the radio frequency detector may be positioned about the patient's body and configured to receive magnetic resonance signals from the region of interest. The processor is configured to direct the radio frequency source to produce a radio frequency field in successive planar sections of the region of interest at Larmor frequencies such that spins resonant with the Larmor frequency in the particular planar section of the region of interest are excited. The processor is further configured to direct the radio frequency detector to receive magnetic resonance signals produced in each planar section of the region of interest in response to the applied radio frequency field, to compute from the acquired magnetic resonance signals a quantitative metric indicative of discriminatory characteristics of differing tissues or other materials within each such planar section, and to produce human discernable output indicative of such quantitative metric.

Also disclosed herein are methods of detecting tissue properties in a patient, comprising selecting a target volume on a patient, exciting the water and fat molecules of the target area with a device configured as described above, and determining the tissue properties by determining the water concentration in the target volume. These methods may be used to detect subdural blood in the brain, edema of the brain, acute stroke, subdural effusions, liver fibrosis, edema in the liver, and blood flow. These methods may also be repeated over a period of time to monitor changes in tissue properties, patient recovery, or disease advancement.

Also disclosed herein are methods for evaluating and examining abdominal organs and abdominal pain. One specific example includes a method of detecting hepatic steatosis, comprising selecting a patient suspected of having or being susceptible to hepatic steatosis, exciting the water and fat molecules of a target area with a magnetic field, measuring the ratio of water molecules to fat molecules, and determining whether the patient has hepatic steatosis, wherein the magnetic field is generated by a portable MRI device in accordance with at least certain aspects of the present invention. Measurements may be taken at more than one location prior to making a diagnosis.

Also disclosed herein is a method of generating an imaging window of interest for a device according to at least certain aspects of the invention, comprising selecting a radio frequency to create the window depth of interest, and selecting a bandwidth to set the size of the window.

### BRIEF DESCRIPTION OF THE DRAWINGS

The numerous advantages of the present invention may be better understood by those skilled in the art by reference to the accompanying figures in which:

FIG. 1 is a schematic view of a system in accordance with certain aspects of an embodiment of the invention.

FIG. 2 is close-up schematic view of a portion of the system of FIG. 1.

FIG. 3 is a schematic view of a control system for use with the system of FIG. 1

FIG. 4 is an exemplary code listing for use by the control system of FIG. 3.

FIG. 5 is a schematic flowchart showing an exemplary method in accordance with certain aspects of an embodiment of the invention.

FIG. 6 is a close-up schematic view of a portion of the system of FIG. 1 in accordance with further aspects of an embodiment of the invention.

FIG. 7 is a schematic flowchart showing an exemplary method in according with still further aspects of an embodiment of the invention.

FIG. 8 is an exemplary representation of a graphic image that may be generated by the method of FIG. 7.

### DETAILED DESCRIPTION

The invention summarized above may be better understood by referring to the following description, claims, and accompanying drawings. This description of an embodiment, set out below to enable one to practice an implementation of the invention, is not intended to limit the preferred embodiment, but to serve as a particular example thereof. Those skilled in the art should appreciate that they may readily use the conception and specific embodiments disclosed as a basis for modifying or designing other methods and systems for carrying out the same purposes of the present invention. Those skilled in the art should also realize that such equivalent assemblies do not depart from the spirit and scope of the invention in its broadest form.

A method, device and system are described for a portable MRI device. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

Some embodiments of the invention are described below in the context of testing for hepatic steatosis. However, it should be understood that that the device and system may be used in a wide range of applications requiring tissue imaging and analysis. Also, many embodiments are described which exclusively use electronic components; but, in other embodiments, mechanical, chemical, optical or other components are used, in whole or in part, or in any combination. One having ordinary skill in the art would recognize minor changes that would be necessary to adapt the system for different uses. These modifications should be considered part of the invention because they do not deviate from its overall spirit.

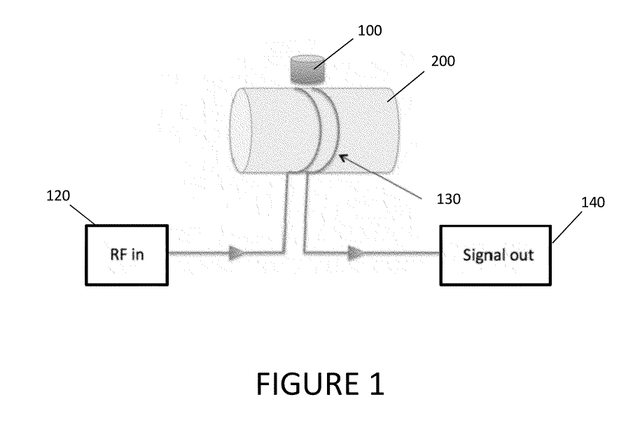

A MRI system is provided and shown schematically in FIG. 1. The basic elements of a magnetic resonance system is a magnetic field generator 100, such as a magnet, that generates a magnetic field that aligns the spins of the tissue within a patient 200 to be measured, a means 120 to apply radio frequency (RF) power to excite (flip) the spins, a gradient field 130 to purposely diphase and rephrase the spins, and a receiver element 140 to receive the magnetic resonance signals. These devices may be portable and handheld.

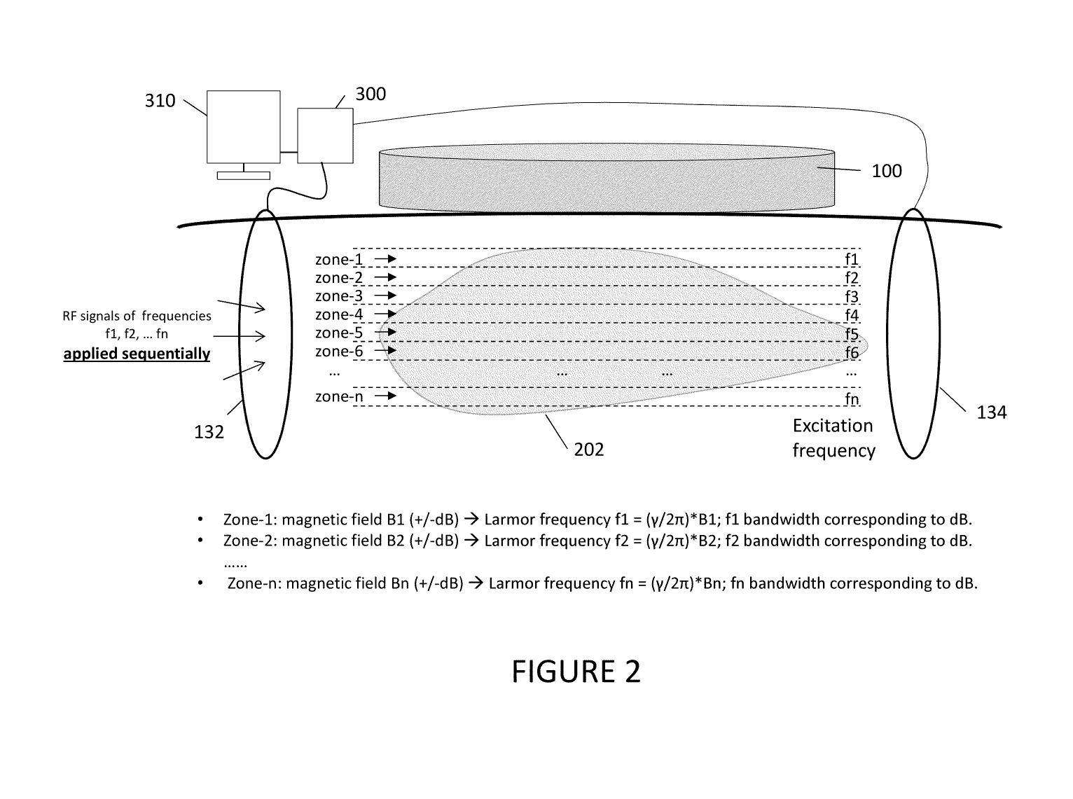

In use, and in accordance with certain aspects of an embodiment of the invention, such MRI system provides portable magnetic resonance capable of determining discriminatory tissue characteristics in a planar section of a region of interest within a patient's body. With reference to the schematic view of FIG. 2, as the characteristics of the magnet 100 used in the system are known, and the tissue characteristics within a patient's body 200 are known, a magnetic field of known field strength may be produced within a region of interest 202 in a patient's body, such as a region of interest within a patient's liver that is to be evaluated for fat content, with the magnetic field generator 100 positioned outside of the patient's body 200, and more preferably hand held in proximity to the patient's body 200. The RF source may comprise a coil 132 that may be positioned about the patient's body 200 and configured to apply an RF field to the region of interest 202, and the radio frequency detector may be a coil 134 positioned about the patient's body 200 and configured to receive magnetic resonance signals from the region of interest 202. The processor 300 is configured to direct the radio frequency source 132 to produce a RF field in successive planar sections 210 of the region of interest 202 at Larmor frequencies such that spins resonant with the Larmor frequency in the particular planar section 210 of the region of interest 202 are excited. More particularly, the Larmor frequency of molecules in a single planar section 210 of the region of interest 202 within the patient's body is proportional to the strength of the magnetic field within such planar section 210 that is generated by the magnet 100 positioned outside of and adjacent to the patient's body 200. As the strength of the magnetic field decreases as it extends further into the patient's body 200 and away from the magnet 100 itself, the Larmor frequency necessary to excite protons at deeper planar sections 210 of the region of interest 202 likewise decreases. Thus, the processor 300 varies the excitation frequency at frequency source 132 to produce a Larmor frequency specific to the field strength at the specific planar section 210 of the region of interest 202 that is then under analysis. Placement of a magnet 100 or magnetic field generator outside of the patient's body 200 and adjacent to the region of interest 202 produces a varying magnetic field within the region of interest 202, allowing selective MRI signal acquisition at any desired depth for image formation or spectrum analysis.

The processor 300 is further configured to direct the radio frequency detector 134 to receive magnetic resonance signals produced in each planar section 210 of the region of interest 202 in response to the applied radio frequency field. The processor 300 may form a part of computing system 310. The processor 300 may be configured to process the received magnetic resonance signals into corresponding magnetic resonance data and to send said data to the computing system 310. The computing system 310 may include memories, micro-processors, digital storage media, a computer display, programming modules, and software packages.

The computing system 310 may include a software package configured to analyze the magnetic resonance data received from the processor 300. The software package may be configured to determine from the received data a quantitative metric indicative of discriminatory characteristics of differing tissue within each planar section 210. The software package may further include a module configured to display on the computer display (e.g. via a dedicated interface) the quantitative metric determined from magnetic resonance data.

In a standard MRI system, the design is based on the desire to image a large volume in three dimensions, which requires large, very homogeneous magnetic fields, and large rapidly switched gradients. However, one goal of the system described herein is only to measure the fat content at a point (or a small collection of points) in a target volume, such as a liver. Since clinically significant hepatic steatosis involves much or all of the liver (focal fatty infiltration is felt to be of no or limited significance) sampling of a limited number of points in the liver would be sufficient for diagnosis and follow-up. Because of this the need for large, very homogenous magnetic fields and for large, rapidly switched gradients is reduced.

Magnet 100 may be a permanent magnet, a solenoid, a bar magnet, an electromagnet, or such other magnetic field generator as may be desirable for a particular application, so long as such magnetic field generator is provided in a compact, hand-held form. Moreover, the magnetic field generator may be in the form of multiple permanent magnets arrayed within a single enclosure. In any case, the magnetic field generator is configured to generate a magnetic field having a known field strength at varying planar sections within a region of interest within a patient's body. The magnetic field strength may generally range between 100 gauss and 1000 gauss, but may be altered as desired. In certain configurations, for example, the field strength may be between 200 and 250 gauss. In yet other configurations, the field strength may be greater than 1000 gauss. In the event that the magnetic field generator is in the form of an electromagnet, a power supply may also be provided, such as a battery or an AC power adapter.

Varying magnet configurations, as have been previously disclosed, may likewise be used without departing from the spirit and scope of the invention. Particularly, as differing magnet configurations will have known field strengths based on their configuration and known effects on tissue types of known composition, the system described herein may be readily configured by those skilled in the art to adjust for differences in both system design and patient physiology to which the imaging methods disclosed herein are applied. In any case, magnet 100 is preferably maintained as a relatively small magnet designed to produce a low magnetic field as compared to the strength of magnetic fields typically generated by traditional MRI systems.

With continued reference to FIG. 2, coils 132 and 134 are in electrical communication with processor 300, and may be positioned around the patient's body 200 on opposite sides of magnet 100.

In certain configurations, a single RF coil may be provided. In this configuration, as RF energy is applied to a planar section 210 of the region of interest 202, the effect of the RF field is to first de-phase and then re-phase the spins of protons within the tissue that comprises such planar section of the region of interest, creating an “echo” that enables the detection of the signals by coil 134. Alternative methods and means may be used in place of gradient coils 132 and 134. In certain configurations, two 90 degree excitations with different read-out times may be used. This method is further described below in Example 1. Other configurations use inversion recovery techniques to separate fat and water.

In other configurations (and particularly that shown in FIG. 2), both coils 132 and 134 are provided. In this configuration, coil 132 transmits the radio frequency signal and coil 134 receives the magnetic resonance signals. This configuration may further include a gradient coil (not shown) to further localize the target area.

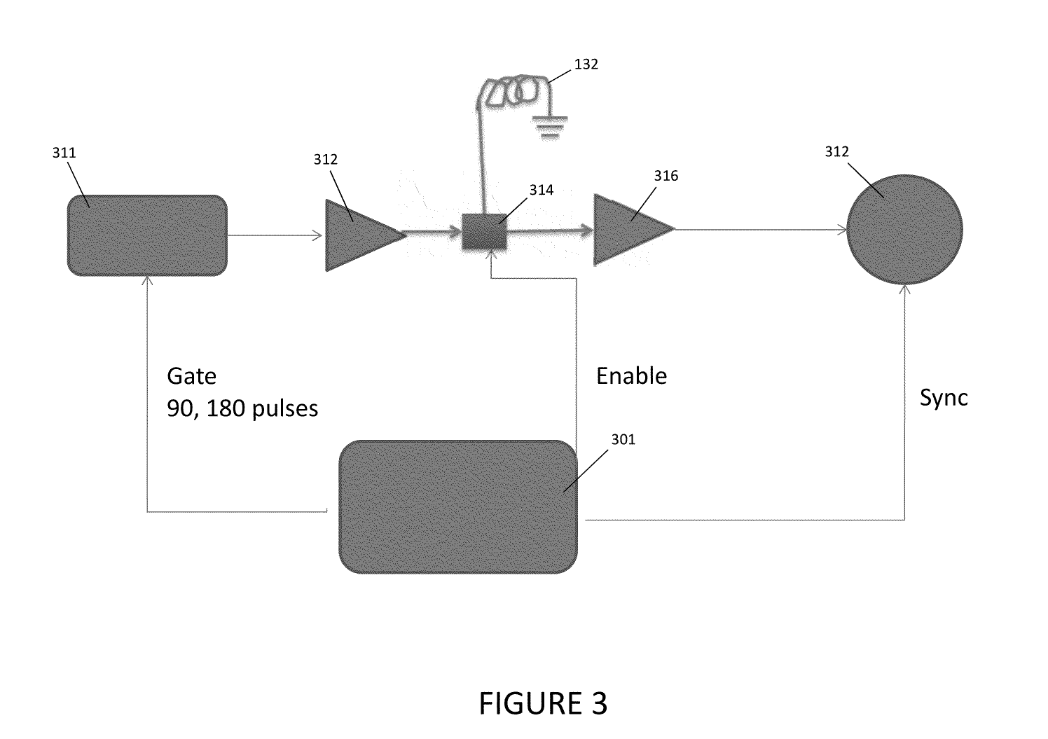

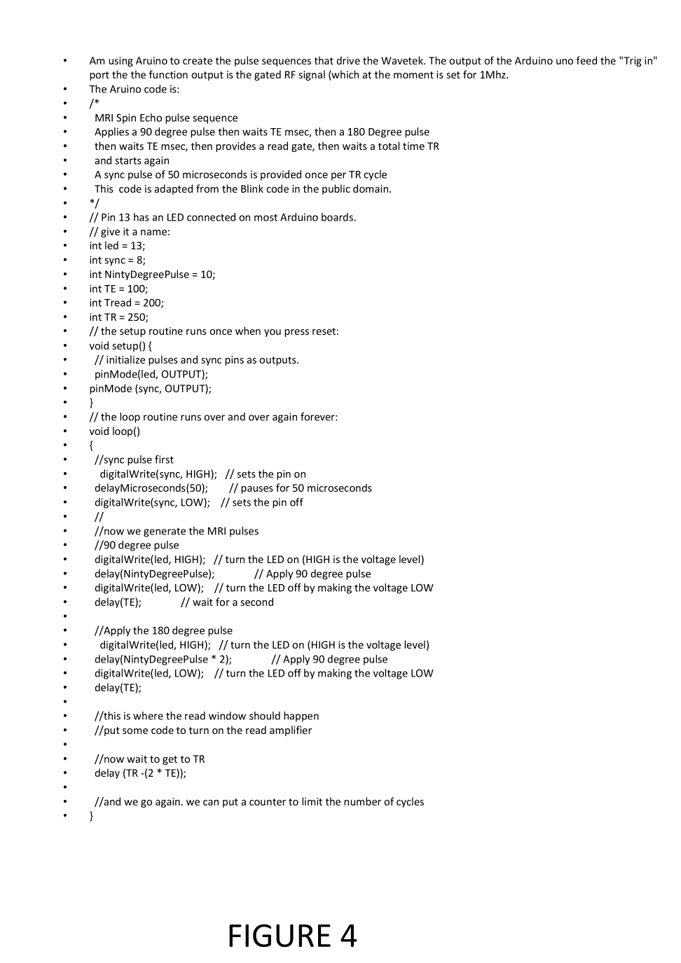

FIG. 3 shows a schematic view of a control system for use with the foregoing system of FIG. 2 (showing, by way of non-limiting example, use of a single RF coil 132), which may be implemented by processor 300. Such control system includes a controller, such as by way of non-limiting an Arduino Controller 301, which sends RF drive signals to a Function Generator 311 to generate RF signals as discussed in the examples below. A power amplifier 312 may be provided to amplify the RF signal. A transmit/receive switch may be provided to change modes of operation of RF coil 132 from a transmit mode to a receive mode. The received magnetic resonance signals may then be directed to output device 318, optionally after being amplified through an RF amplifier 316. Controller 301 may send signals to function generator 311, may control the operational mode of transmit/receive switch 314, and may control the settings of output device 312, and more particularly format the output into a proper human readable display for display on output device 312 using signal processing techniques known to those of ordinary skill in the art. FIG. 4 provides an exemplary passage of code suitable for causing controller 301 to operate as described here. Those skilled in the art will recognize that controller 301 may be implemented by processor 300, and that output device 312 may be a component of computing system 310 (and thus that such elements need not be separate elements from those shown in the system of FIG. 2) without departing from the spirit and scope of the invention.

While not specifically shown in the Figures, processor 300 may also provide data acquisition and general data processing capabilities, data storage, and a user interface allowing an operator to engage the functions described herein, including by way of non-limiting example configuration of the RF field to be generated in order to apply a Larmor frequency to successive planar sections of a region of interest within a patient's body, based upon the magnetic field strength at such planar section. Moreover, such data processing functions of processor 300 may generate a display indicative of the presence of varying tissue characteristics in a patient, and preferably a ratio or other discriminating comparison of an amount of tissue having a first characteristic to an amount of tissue having a second characteristic, such as an amount of fat versus an amount of water in a given planar section of a region of interest within a patient's body.

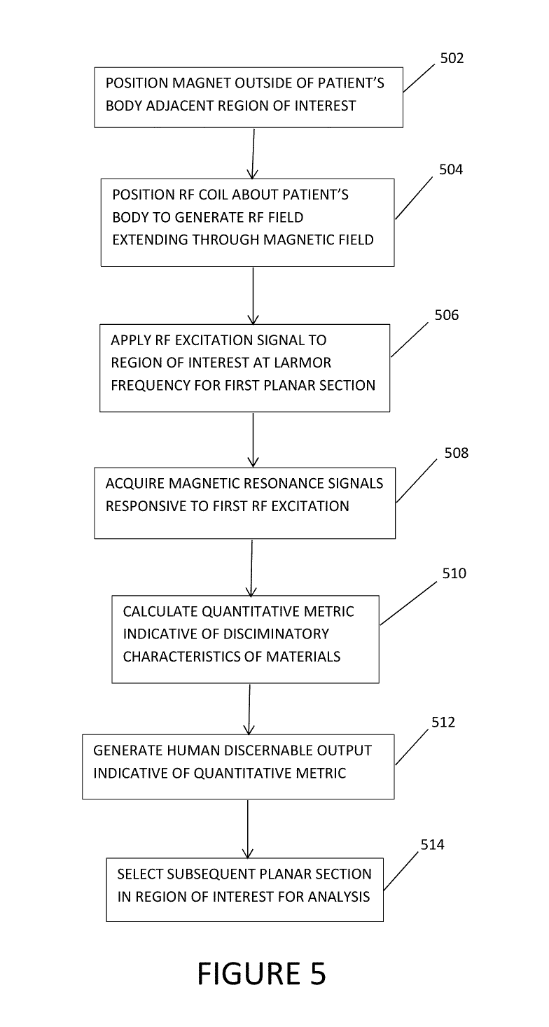

FIG. 5 is a schematic view of an exemplary method for detection of discriminatory tissue characteristics within a patient's body in accordance with certain aspects of the invention.

At step 502, portable magnet 100 is positioned adjacent a patient's body so as to generate a magnetic field that extends into a region of interest within the patient's body. At step 504, a RF coil is then positioned about the patient's body in a position so as to generate an RF signal that will extend through the magnetic field. At step 506, an RF excitation signal is applied to the region of interest at a Larmor frequency for protons within a first selected planar section of the region of interest, such that magnetic resonance signals will be acquired from such protons. Then, at step 508, magnetic resonance signals responsive to the first RF excitation are acquired, and at step 510, a quantitative metric (e.g., fat-to-water ratio) is calculated indicative of discriminatory characteristics of differing tissues or other materials within the selected planar section of the region of interest. Step 510 may include determining a spectrum, via Fourier Transform Analysis, of the acquired magnetic resonance signals and/or the determination of one or more frequency peaks (and associated areas under said peaks) in said spectrum. Preferably, at step 512, human discernable output is generated indicative of such quantitative metric, which may in certain configurations comprise an image indicative of the quantitative metric. For example, a software module may cause the display on a computer display of a value of fat-to-water ratio. Thereafter, at step 514, a subsequent planar section of the region of interest may be selected, and the foregoing steps repeated at a second Larmor frequency for protons within such subsequent planar section of the region of interest, until the full region of interest has been analyzed.

A system configured as described above is portable and far easier to use in a traditional physician's office, but is nonetheless capable of providing a simplified, safe, real-time display diagnosis of discriminatory tissue characteristics within a patient's body, such as the existence of some amount of fat tissue when compared to other tissue at a designated location within the patient's body. Moreover, the hand-held MRI device is not limited to detecting hepatic steatosis. Certain configurations may be used to detect properties of other types of tissue at a point of interest, or the device may be used as a line or plane at a time imager. Some example uses include detection of subdural blood in the brain, edema of the brain, acute stroke, subdural effusions, liver fibrosis, edema in the liver, and blood flow. The imaging device may focus on a particular window of interest by setting frequency and bandwidth of the radio frequency. The frequency of the radio frequency field will determine the depth of the window. The bandwidth of the RF frequencies will determine the size of the window. This allows the user to preselect the depth, size, and location of the target.

Images and tissue properties may be captured in less than one second. Therefore, a typical user can stabilize the hand-held device.

A method for detecting hepatic steatosis is described according to an exemplary embodiment of the invention. The method may be practiced by using the magnetic resonance system described above with reference to FIGS. 1-5. The frequency of rotation of water spins is slightly higher than the rotation frequency of the spins of fat at the same field, such that if the time at which the echo is created is chosen carefully, the echo can be created with the water and fat spins “in phase” (i.e. adding in strength) or “out of phase” (i.e, subtracting in phase). If two signals are collected, one in phase and the second out of phase, then if there is significant fatty infiltration, there will be a significant difference in signal between the two acquisitions, with the difference proportional to the amount of fat in the tissue. If there is no fat, there will be no difference in signal.

The actual difference in frequency for protons in fat or water molecules is ˜3.5 ppm. Thus, at field strengths of 1.5 Tesla (+15,000 gauss), the Larmor frequency is ˜63.86 Mhz, which would put the difference in frequency between the water and fat molecules at ˜220 hz. At a field strength of 250 gauss (an easily achievable field for a hand held system), the Larmor frequency is ˜1 Mhz and the difference frequency would be ˜3.7 hz. This implies that the spins of fat and water molecules would be in-phase 3.7 times/sec.

Thus, if the spins are excited at time zero (t=0), then the fat and water spins would be 180 degrees out of phase at t=0.135 seconds, then back in phase at t=0.27 seconds, then 180 degrees out of phase again at t=0.4 seconds, and so on. The total signal when the fat and water spins are in phase is proportional to the number of water spins plus the number of fat spins. The signal when the spins are out of phase is proportional to the number of water spins minus the number of fat spins. By acquiring the signals at these two points and adding them, the number of water spins can be estimated, and then by subtracting them the number of fat spins can be estimated. The ratio in this is example is the quantitative degree of hepatic steatosis. This method may be repeated over time to monitor progression or regression of the disease.

The software package of the magnetic resonance system may include a module configured to determine the ratio between the amount of water and the amount of fat included in section 210. The software package may determine the relative amounts of water and fat by performing Fourier transform analysis of the magnetic resonance signal data and by taking into account the fact that, at the same magnetic field, the rotation frequency of the water spins is slightly higher than the rotation frequency of the fat spins.

The software package may further include a module configured to display on the computer display (e.g. via a dedicated interface) the magnetic resonance data. The software may determine the fat-to-water ratio for various sections 120 and display the obtained values on the interface. The software may create a graph of the fat-to-water ratio (corresponding to a series of planar sections 120) as a function of the section depth into the body. The software may create 1-dimensional images corresponding to the fat content, the water content, or the fat-to-water ratio of a set of magnetic resonance signals acquired from a series of successive sections 120 (e.g. sections shown by zone-1 to zone-8 in FIG. 2).

In another exemplary embodiment, a real time “B-mode” MRI imaging system may be implemented. The depth below the surface at which spins are excited (flipped) by the RF signal is determined by Larmor's equation (ω=γBₒ) where γ is the gyromagnetic ratio, a constant of the atom (hydrogen in this case) being excited, which has a value such that at 250 gauss the frequency ω is 1 Mhz. In the proposed configuration, the field varies with depth below the surface into the patient and so that the RF frequency that will excite (i.e. be resonant with) the spins will also vary with depth—in a fixed manner determined by the geometry. If, instead of applying a single RF frequency, a band of RF frequencies are applied, then spins within tissues over some depth below the surface would be excited, with the depth encompassed determined by the bandwidth of the RF.

Using conventional MRI techniques (e.g. “spin-flip” or gradient echo), MRI signals would be created at a band of frequencies which would again be determined by the depth at which they were created. A spectrum analysis (i.e. Fourier transform of the received signal) would map the signal spectrum into depth and a line image—similar to that in a single line of a B-scan ultrasound image—would be created. The advantage of this technique is that conventional MRI methods (i.e. T1 or T2) could be used to create line images with high soft tissue contrast. By manually scanning the hand-held applicator over the patient, a complete 2-D (and even a 3-D) image could be created. This system could find application in a physician's office, in the field for emergency evaluation, and to guide procedures.

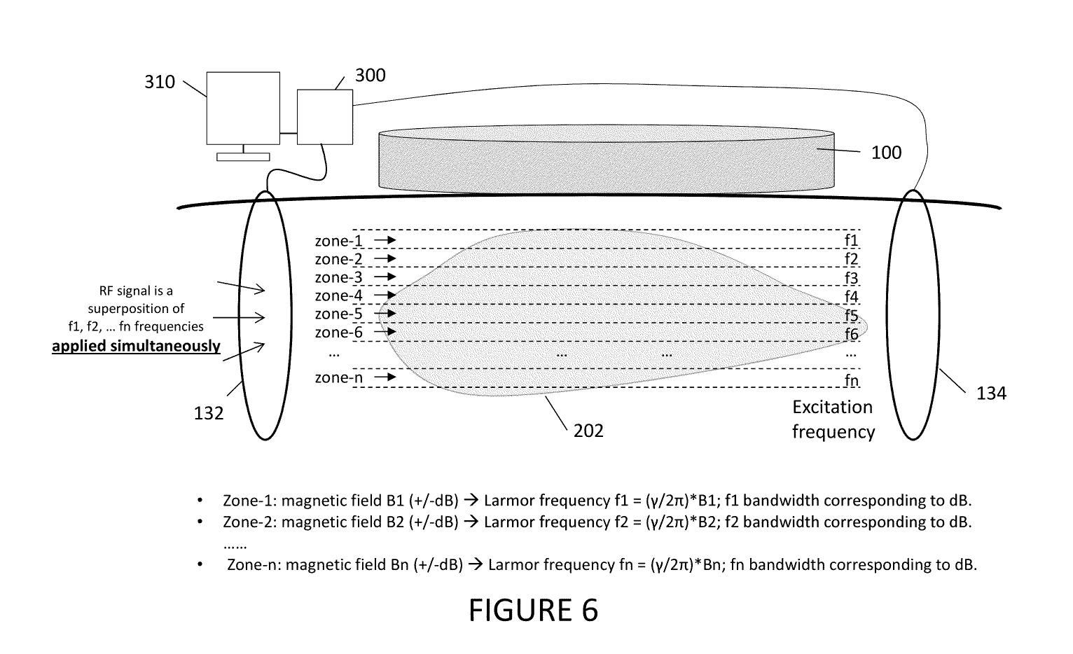

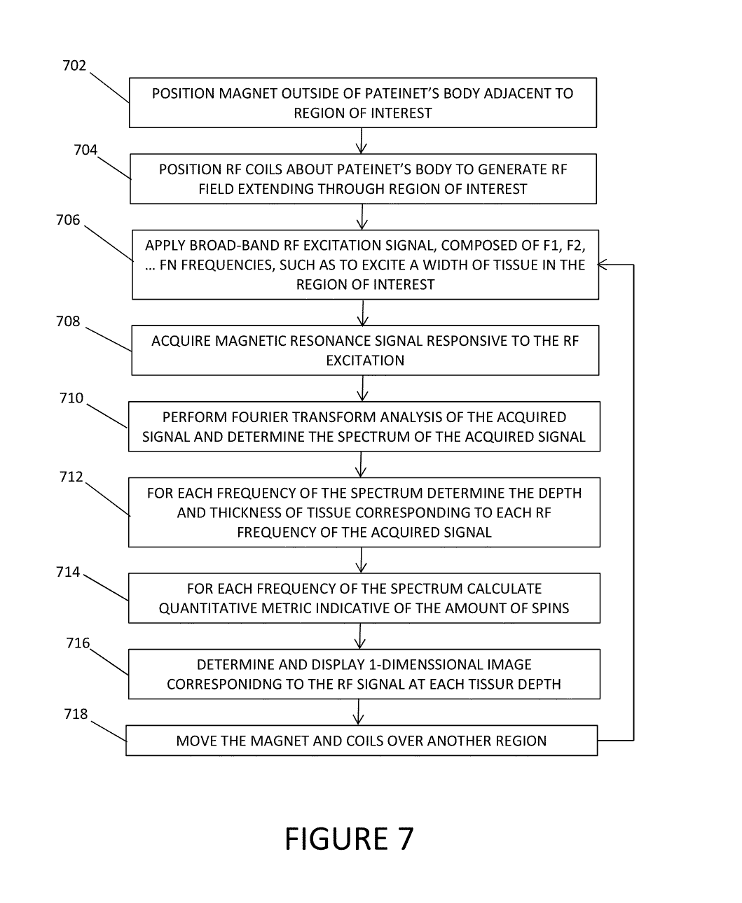

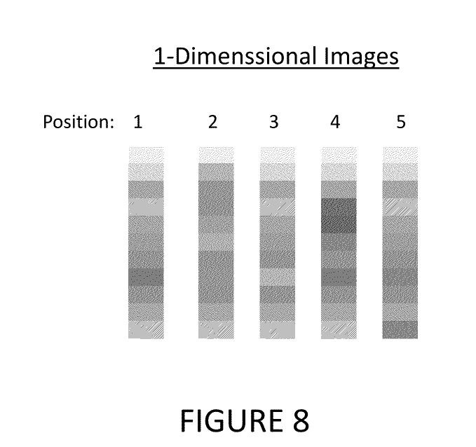

The “B-mode” MRI imaging system may include substantially the same components as the magnetic resonance system described with reference to FIGS. 1-3. A method for using the “B-mode” MRI imaging system, according to an exemplary embodiment, is explained in the following with reference to FIG. 6 and the schematic flowchart of FIG. 7. After the magnet is positioned at step 702 and the RF coils are positioned at step 704, coil 132 applies a band of frequency RF signal (composed of a superposition of RF signals having frequencies f1, f2, . . . fn) at step 706 on the region of interest 202. The RF signal excites the spins in all zones (i.e. zone-1 to zone-n) at the same time. The excited spins emit an RF signal which is detected by the coil 134, thereby generating an electronic signal in coil 134 at step 708 corresponding to the RF signal emitted by the excited spins. The frequency spectrum of the electronic signal is determined (e.g., by Fourier transform analysis) at step 710. The frequency spectrum is used to determine the RF signal generated by each of the zones “1” to “n,” with each RF signal assigned to a determined depth and thickness of tissue at step 712. Further, the amount of spins (e.g. number of protons or hydrogen content) in each of the zones “1” to “n” is determined from the spectrum and RF signal at step 714. A graph may be created showing the generated signal vs. depth for each of the zones “1” to “n”. Finally, at step 716, a 1-dimensional image is created mapping the amount of spins (e.g. hydrogen content) at each tissue depth corresponding to the zones “1” to “n” (e.g. the luminosity of each point on the line representing the amount of spins at the corresponding depth as seen in FIG. 8). The entire data acquisition and display processes may take a short amount of time (e.g. seconds).

After acquiring a first 1-D image the operator may move the magnet (and the coils) at step 718 to another position of the patient's body and collect another 1-dimensional image corresponding to the tissue under the magnet. Further, 1-dimensional images may be acquired at different points over the patient's body, by scanning the magnet over the patient and collecting data, thereby obtaining a complete 2-D (or 3-D) image corresponding to the scanned area. The imaging system may be incorporated into a hand-held applicator. The imaging system/hand-held applicator may include a tracking sensor (e.g. electromagnetic tip sensor, optical tracking, accelerometer) to aid in determining the position of the magnet during the scanning process.

The computer 310 of a “B-mode” MRI imaging system may include a software package configured to analyze the “B-mode” magnetic resonance data. The software package may be configured to determine from the received data a quantitative metric indicative of discriminatory characteristics of differing tissues within each section 210 (e.g. each of the zones “1” to “n” in FIG. 6). Further, the software package may include a module configured to determine the amount of spins included in each section 210 (i.e. at each depth in the tissue). The software package may determine the number of spins at each depth by performing Fourier transform analysis of the magnetic resonance signal data.

The software package may further include a module configured to display on the computer display (e.g. via a dedicated interface) the magnetic resonance data. The software may create a graph of the amount of spins (corresponding to a series of planar sections 120) as a function of the section depth into the body and display the graph on the dedicated interface. The software may create and display on the interface 1-dimensional images corresponding to the amount of spins at each depth. The software may include a module configured to determine a 2-D image corresponding to the magnetic resonance data acquired during scanning the magnet over the patient's body and display said 2-D image on the computer display. An exemplary view of such an image that could be produced by such system is shown in FIG. 8.

The spatial resolution of MRI systems depends on the signal to noise ratio (SNR) of the system, which itself depends on a number of factors such as field strength, the receiver coil arrangement, and the total signal acquisition time, among other factors. The SNR is approximately proportional to the magnetic field strength, such that we would expect that in a system working at ˜250 gauss, the resolution would be ˜60 times worse than that achieved at 1.5 T. But in a recent imaging study done at 1000 gauss (0.1 T), image resolutions of ˜0.5·0.5·0.5 mm3 were obtained (Goetz et. al. J Nucl Med 2008; 49:88-93). This would suggest that it is possible to achieve millimeter level resolutions in the proposed hand held system.

Having now fully set forth the preferred embodiments and certain modifications of the concept underlying the present invention, various other embodiments as well as certain variations and modifications of the embodiments herein shown and described will obviously occur to those skilled in the art upon becoming familiar with said underlying concept. It should be understood, therefore, that the invention may be practiced otherwise than as specifically set forth herein.

What is claimed is:

1. A portable system for magnetic resonance tissue analysis comprising:
a portable magnetic field generator generating a magnetic field in a first direction;
at least one portable radio frequency coil positioned to transmit radio frequency radiation through at least a portion of said magnetic field; and
a processor having computer executable code thereon configured to:
direct said radio frequency coil to produce a first radio frequency field at a first Larmor frequency for a first planar section of a region of interest within a patient;
receive magnetic resonance signals having at least two different frequencies, the received signals being produced in said first planar section of said region of interest in response to said first radio frequency field;
calculate a difference in signal between at least some of said received magnetic resonance signals having different frequencies;
compute a value indicative of a concentration of fat within said first planar section, wherein said value is proportional to said difference in signal; and
generate human discernable output indicative of said value at said first planar section.

2. The system of claim 1, wherein said value further comprises a ratio of fat to water within said first planar section.

3. The system of claim 2, wherein said computer executable code is further configured to:
direct said radio frequency coil to produce a second radio frequency field at a second Larmor frequency for a second planar section of said region of interest;
receive magnetic resonance signals having at least two different frequencies, the received signals being produced in said second planar section of said region of interest in response to said second radio frequency field;
calculate a difference in signal between at least some of said received magnetic resonance signals having different frequencies in said second planar section;
compute a value indicative of a concentration of fat within said second planar section, wherein said value is proportional to said difference in signal; and
generate human discernable output indicative of said values at said first and second planar sections.

4. The system of claim 1, wherein said magnet is selected to produce a magnetic field of sufficient strength to extend through a patient's liver so as to enable the radio frequency excitation of spins inside the liver tissue throughout the volume of the liver.

5. The system of claim 1, wherein said magnetic field is of sufficient strength to enable the radio frequency excitation of water and fat molecules within a patient's liver at differing planar sections of said patient's liver.

6. The system of claim 1, wherein said computer executable code is further configured to determine the presence of hepatic steatosis within said patient.

7. The system of claim 1, wherein said magnetic field generator further comprises at least one permanent magnet.

8. The system of claim 1, wherein said magnetic field generator further comprises an electromagnet.

9. The system of claim 1, further comprising a second portable radio frequency coil positioned to receive magnetic resonance signals from said region of interest.

10. A method of using the portable system of claim 1 to detect the presence of hepatic steatosis within a patient, comprising the steps of:
positioning said magnetic field generator to direct a magnetic field toward a patient's liver;
directing a radio frequency field through at least a first planar section of said patient's liver;
receiving magnetic resonance signals produced in said first planar section;
causing said processor to calculate a difference in signal between at least some of said received magnetic resonance signals;
causing said processor to compute a value indicative of a concentration of fat within said first planar section, wherein said value is proportional to said difference in signal; and
causing said processor to generate human discernable output indicative of said value at said first planar section.

11. A portable system for magnetic resonance tissue analysis comprising:
a portable magnetic field generator generating a magnetic field in a first direction;
a first portable radio frequency coil positioned to transmit radio frequency radiation through at least a portion of said magnetic field;
a second portable radio frequency coil positioned to receive magnetic resonance signals from said magnetic field; and
a processor having computer executable code thereon configured to:
direct said first radio frequency coil to produce a broad-band radio frequency field at multiple Larmor frequencies for multiple planar sections of a region of interest within a patient;
receive magnetic resonance signals produced in said multiple planar sections of said region of interest in response to said broad-band radio frequency field;
compute a depth and thickness of tissue corresponding to varying frequencies of said received magnetic resonance signals;
for each computed depth and thickness, calculate a quantitative metric indicative of an amount of proton spins; and
generate a display indicative of said quantitative metric at each computed depth and thickness.

12. The system of claim 11, wherein said processor is further configured to:
perform Fourier Transform Analysis on said received magnetic resonance signals to determine a frequency spectrum of said received magnetic resonance signals.

13. The system of claim 11, wherein said display further comprises a 1-dimensional image representing varying amounts of soft tissue within said region of interest.

14. The system of claim 11, wherein said magnet is selected to produce a magnetic field of sufficient strength to extend through said region of interest within the patient's body so as to enable the radio frequency excitation of spins inside the liver tissue throughout the volume of the liver.

15. The system of claim 11, wherein said magnetic field is of sufficient strength to enable the radio frequency excitation of water molecules within soft tissues at differing planar sections of said region of interest.

16. The system of claim 11, wherein said magnetic field generator further comprises an electromagnet.

17. The system of claim 11, wherein said magnetic field generator further comprises at least one permanent magnet.

18. A method of using the portable system of claim 11 to image soft tissue within a region of interest in a patient's body, comprising the steps of:
(a) positioning said magnetic field generator to direct a magnetic field toward a patient's liver;
(b) directing a broad-band radio frequency field through at least multiple planar sections of said region of interest;
(c) receiving magnetic resonance signals produced in said multiple planar sections;
(d) causing said processor to compute a depth and thickness of tissue corresponding to varying frequencies of said magnetic resonance signals;
(e) causing said processor to calculate, for each computed depth and thickness, a quantitative metric indicative of an amount of proton spins; and
(f) causing said processor to generate a display indicative of said quantitative metric at each computed depth and thickness.

19. The method of claim 18, further comprising the step of moving said magnetic field generator and coils to a new position, and repeating steps (b) through (f) at said new position.

20. The method of claim 18, further comprising the steps of creating and displaying a 1-dimensional image corresponding to the computed quantitative metrics at each computed depth and thickness.
